(19) United States
(12) Patent Application Publication
(10) Pub. No.: US 2026/0370030 A1
(43) Pub. Date: Nov. 19, 2026

(54) INTELLIGENT CHARGING SOUND SYSTEM BASED ON DEVICE IDENTIFICATION

(71) Applicant: Jueqing HE, Guangzhou (CN)

(72) Inventor: Jueqing HE, Guangzhou (CN)

(21) Appl. No.: 19/676,782

(22) Filed: May 13, 2026

(30) Foreign Application Priority Data
May 15, 2025 (CN) 202510628359.1

(51) Int. Cl. H02J 7/90; G06F 3/16; H02J 7/47; H04R 1/02; H04R 3/04; H04R 29/00; H05K 7/20; H05K 9/00

(52) U.S. Cl. CPC H02J 7/977; G06F 3/165; H02J 7/47; H04R 1/02; H04R 3/04; H04R 29/001; H05K 7/20909; H05K 7/20936; H05K 9/002

(57) ABSTRACT

An intelligent charging sound system based on device identification includes a charging unit, a speaker unit and a first unit, a controller with an integral charging module configured to respond to a starting signal to obtain a device model of a target device as a first model, obtain a temperature detected by the first unit as a first temperature, set a charging working mode to be charging if the first temperature is greater than a first threshold corresponding to the first model, otherwise, control the charging unit to apply a current to the target device for preheating a battery thereof according to the first temperature and the first model, set the charging working mode to be charging after preheating the battery, control the charging unit to charge the target device according to the temperature and a charging configuration corresponding to the first model when charging the battery.

### 1. CROSS-REFERENCE TO RELATED APPLICATION

This application claims the benefit of priority from Chinese Patent Application No. 202510628359.1 entitled “INTELLIGENT CHARGING SOUND SYSTEM BASED ON DEVICE IDENTIFICATION” and filed on May 15, 2025, the content of which is hereby incorporated by reference in its entire by reference.

### BACKGROUND

### 2. Technical Field

The present disclosure generally relates to the field of charging sounds, and especially relates to an intelligent charging sound system based on device identification.

### 3. Description of Related Art

Rechargeable sound systems are widely used in modern technological life. A conventional charging sound system generally adopts a fixed charging mode, which results in lacking adaptability to charging environments; especially under low temperature conditions, the charging efficiency significantly decreases. In addition, devices with different models have different charging requirements that include: differences in battery characteristics, and fixed charging modes unable to adapt to personalized requirements of different devices.

### SUMMARY

The technical problems to be solved: in view of the shortcomings of the related art, the present disclosure provides an intelligent charging sound system based on device identification which can solve the technical problems that the conventional charging sound system is generally charged by a fixed charging mode, lack adaptability to charging environments, and unable to adapt to personalized requirements of different devices.

In order to solve the above objectives, an intelligent charging sound system based on device identification according to an embodiment of the present disclosure includes: a controller, a power supply unit, a charging unit, a speaker unit and a first unit, the power supply unit configured to supply power to the controller, the charging unit, the speaker unit and the first unit, and the first unit configured to detect a temperature of a target device; and wherein
a charging module is integrated with the controller and configured to:
obtain a start signal, respond to the start signal, and obtain a device model of the target device as a first model;
obtain the temperature detected by the first unit, and take the Temperature as a first temperature;
setting a charging working mode to be charging if the first temperature is greater than a first threshold corresponding to the first model; otherwise, controlling the charging unit to apply a current to the target device for preheating a battery of the target device based on the first model and the temperature detected by the first unit, and setting the charging working mode to be charging the battery after preheating the battery; and
when the charging working mode is charging the battery, controlling the charging unit to charge the target device based on the temperature detected by the first unit and a charging configuration corresponding to the first model.

The intelligent charging sound system based on device identification of the present disclosure is provided to detect the temperature of the target device and identify the device model of the target device, when the temperature is greater than the corresponding threshold, the target device is charged directly, and when the temperature is below the corresponding threshold, a battery of the target device is preheated and then recharged the target device, which is adaptable to the charging environment, improves charging efficiency, reduces battery decay, protects battery safety, and extends a service life of the battery. Moreover, according to the charging configurations corresponding to different device models, the target device is charged, which is automatically adapted to the personalized requirements of different devices, and avoids risks of overcharging or undercharging of the battery.

### BRIEF DESCRIPTION OF THE DRAWINGS

In order to more clearly understand the technical solution hereinafter in embodiments of the present disclosure, a brief description to the drawings used in detailed description of embodiments hereinafter is provided thereof. Obviously, the drawings described below are some embodiments of the present disclosure, for one of ordinary skill in the related art, other drawings can be obtained according to the drawings below on the premise of no creative work.

FIG. 1 is a block diagram of an intelligent charging sound system based on device identification in accordance with an embodiment of the present disclosure.

FIG. 2 is a partially schematic diagram of the intelligent charging sound system of FIG. 1.

FIG. 3 is a schematic view of a housing of the intelligent charging sound system of FIG. 1.

FIG. 4 is a schematic view of an insulation isolation layer of the intelligent charging sound system of FIG. 1.

### DETAILED DESCRIPTION

Reference will now be made in detail to embodiments, examples of which are illustrated in the accompanying drawings. In the following detailed description, numerous specific details are set forth in order to provide a thorough understanding of the subject matter presented herein. Obviously, the implementation embodiment in the description is a part of the present disclosure implementation examples, rather than the implementation of all embodiments, examples. According to the described exemplary embodiment of the present disclosure, all other embodiments obtained by one of ordinary skill in the related art on the premise of no creative work are within the protection scope of the present disclosure.

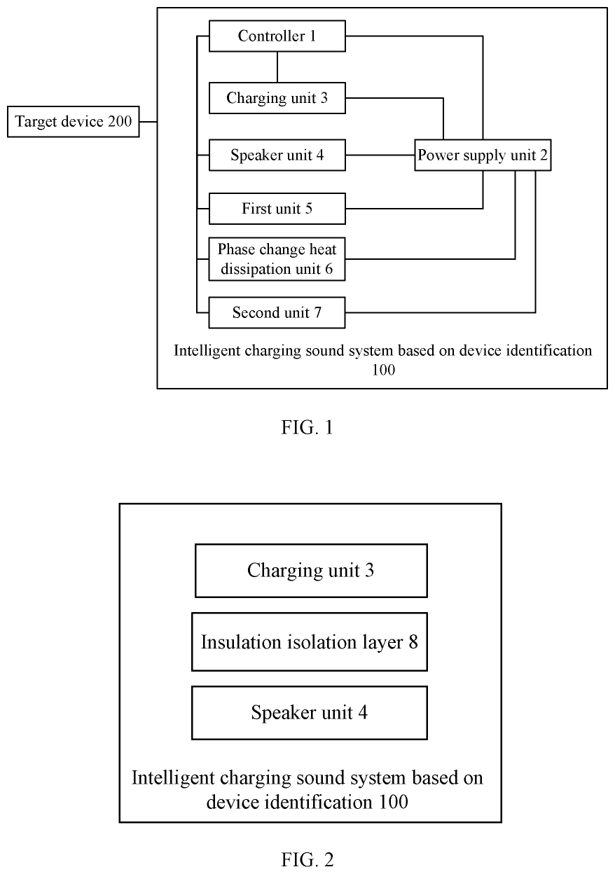

Referring to FIG. 1, an intelligent charging sound system based on device identification 100 according to an embodiment of the present disclosure includes: a controller 1, a power supply unit 2, a charging unit 3, a speaker unit 4 and a first unit 5, the power supply unit 2 configured to supply power to the controller 1, the charging unit 3, the speaker unit 4 and the first unit 5, and the first unit 5 configured to detect a temperature of a target device 200; and wherein
a charging module is integrated with the controller 1 and configured to:
obtain a start signal, respond to the start signal, and obtain a device model of the target device 200 as a first model;
obtain the temperature detected by the first unit 5, and take the temperature as a first temperature;
if the first temperature is greater than a first threshold corresponding to the first model, setting a charging working mode to be charging, otherwise, based on the first model and the temperature detected by the first unit 5, controlling the charging unit 3 to apply a current to the target device 200 for preheating a battery of the target device 200, and setting the charging working mode to be charging the battery after preheating the battery; and
when the charging working mode is charging the battery, controlling the charging unit 3 to charge the target device 200 based on the temperature detected by the first unit 5 and a charging configuration corresponding to the first model.
The target device 200 includes, but is not limited to, a mobile phone, a tablet, and a phone watch.

The controller 1 is a core component of the entire intelligent charging sound system 100, which acts like a brain to be responsible for coordinating and controlling a work of other units. The controller 1 receives information from various units, such as the start signal, and the temperature detected by the first unit 5 etc., and controls the charging unit 3 and the speaker unit 4 etc., to work or not according to pre-set programs and rules to ensure the smooth progress of the entire charging process and the smooth play of audios.

Optionally, the controller 1 is an embedded microprocessor, and responsible for coordinating the operation of various modules and units within the intelligent charging sound system 100 based on the device recognition, executing charging logic judgment and instruction issuance, audio play logic judgment and instruction issuance.

The power supply unit 2 is a part that supplies power to the entire system 100, and just like a heart configured to convert external input electric energy (such as electric energy from the mains supply or battery packs) into voltages and currents suitable for each unit of the system 100, and then supplies the voltages and the currents to the controller 1, the charging unit 3, the speaker unit 4, the first unit 5, respectively, so as to ensure that the above units can work normally.

The power supply unit 2 supports multiple-source inputs (an alternating current (AC) power of 220V from the mains supply, a direct current (DC) power of 12V from a portable power source), and converts the power input to the power supply unit 2 into a power required by the system 100 via an AC-DC conversion subunit (for converting an AC to a DC) and a DC-DC voltage stabilization subunit. The DC-DC voltage stabilization unit has functions of voltage conversion (step-down or step-up) to convert the voltage of the electric energy input to the power supply unit 2 into the voltage required by each unit, which has the function of voltage stabilization to cope with the fluctuations of the electric energy input to the power supply unit 2 and isolate noise interference, and the function of improving power supply efficiency, adapt to different unit requirements and reduce energy conversion losses thereof.

The power supply unit 2 also provides overvoltage and/or overcurrent protection circuits (e.g., TVS diodes and self-recovery fuses) to prevent external power supply abnormalities from damaging the system 100. The power supply unit 2 distributes the electric energy to the controller 1, the charging unit 3, the speaker unit 4, the first unit 5 and other units through multiple output interfaces thereof.

The charging unit 3 is a portion that is specifically responsible for charging the target device 200, and configured to convert the electric energy input from the power supply unit 2 according to the instruction of the controller 1 and output a suitable current and a voltage to the target device 200 to charge a battery of the target device 200. For example, the charging unit 3 can transmit the power supplied from the power supply unit 2 to the battery of the target device 200 according to a certain specification (e.g., a specific voltage and a specific current).

A wireless charging module (a Qi protocol, a 0.1Ω of coil impedance) and a wired quick charging module (a USB PD 3.0+QC4+) are respectively integrated with the charging unit 3, which communicate with the target device 200 through a protocol handshake chip, to obtain charging specifications supported by the device. The charging unit 3 adjusts the output current (0.5 A-5 A) and the voltage (5V-20V) by mosfet switches (semiconductor field effect transistors) and PWM (Pulse Width Modulation) signals according to the instruction of the controller 1. For example, the charging unit 3 outputs a 0.5 A of pulse current (with a duty ratio of 50%), generates heat through the internal resistance of the battery of the target device 200, and increases a temperature to above a threshold within 3 minutes. The charging unit 3 is configured with a current/voltage sampling circuit (such as an INA219 sensor) to monitor a charging status in real time, and feed data back to the controller 1 via an I2C bus.

The speaker unit 4 is mainly responsible for audio related functions. In the intelligent charging sound system 100 based on device identification of the present disclosure, although its primary function is not the charging related function, it is also a part of the system 100, which can play audios according to the instruction of the controller 1, for example, when there is a prompt tone during charging the system 100 or when a user wants to listen to music during charging the system 100, the speaker unit 4 will come into play a role thereof.

The speaker unit 4 supports a Bluetooth, an AUX interface, a Wi-Fi transmission of input audios. After an audio signal is decoded by a DAC chip (Digital-to-Analog Converter) of the speaker unit 4, a 2.1 channel speaker of the speaker unit 4 is driven to play the audios by a power amplifier chip of the speaker unit 4.

The AUX interface is an audio input interface that is used mainly for connecting with an external audio source in the intelligent charging sound system 100. The external audio source can be a device such as an MP3 player, and a cell phone etc. Through the AUX interface, the user can input an audio signal of the external device into the speaker unit 4 for being played.

The Wi-Fi is a technology that allows an electronic device to connect to a wireless local area network (WLAN).

The first unit 5 can be a temperature sensor.

Optionally, a line of the speaker unit 4 for transmitting the audio signal is physically isolated from a line of the charging unit 3, with a distance not less than 5 mm, and twisted pair wires are used to reduce crosstalk thereof.

Relative positions of the controller 1, the power supply unit 2, the charging unit 3, the speaker unit 4 and the first unit 5 can be set according to requirements, which are not limited herein.

The charging unit 3 includes a wired charging subunit and/or a wireless charging subunit. The wired charging subunit is electrically connected with the target device 200 through a charging wire, and provides the electric energy to the target device 200 through the charging wire for charging the target device 200. The wireless charging subunit is in contact with the target device 200, and charges the target device 200 through a wireless charging protocol.

The start signal is a signal to start charging the system 100. It can be triggered by a user through a physical button, or automatically triggered after a hall sensor within the system 100 detects a magnetic field change when the target device 200 is placed in a charging area thereof, or automatically triggered when self-checking of the system 100 is completed after the system 100 is powered on. The controller 1 triggers the start signal to start an initialization process of the charging module by receiving button signals or sensor interrupt signals.

For example, when the target device 200 is connected to the charging unit 3 through a charging interface (such as a USB interface), a level change is generated in a circuit inside the charging interface, and after the level change is detected by the charging unit 3, a signal indicating that a connection is established is sent to the controller 1, which is the start signal.

It can be a device model of the target device 200 input by the user, a model code (such as an identifier “A2484” of iPhone 13) in a tag of the target device 200 can be read by an NFC (Near Field Communication) unit in the system 100, or a preset file of the target device 200 can be obtained through a “Get_Device_Info” command in a USB PD (USB Power Delivery, power transfer protocol) protocol, and the device model of the target device 200 can be obtained by parsing the preset file. The controller 1 calls the NFC driver or the USB PD protocol stack to parse the device model, and stores the device model into an internal EEPROM (electrically erasable programmable read only memory).

The temperature detected by the first unit 5 in real time is obtained, and the temperature that is obtained at this time is taken as a first temperature.

A collecting end of the first unit 5 is in contact with the target device 200 to detect a temperature of the target device 200.

Optionally, the first unit 5 samples the temperature every 200 ms, and transmits the temperature to the controller 1 through the I2C bus. When obtaining the start signal, the controller 1 takes the latest acquired temperature that is obtained as the first temperature. The controller 1 queries a pre-stored threshold table according to the first model, and takes n obtained threshold as a first threshold corresponding to the first model. The controller 1 compares the first temperature with the first threshold, to trigger preheating the target device 200 or direct charging the target device 200.

If the first temperature is greater than the first threshold corresponding to the first model, which means that an ambient temperature is suitable for direct charging the target device 200, and therefore the charging working mode is set to be charging target device 200.

If the first temperature is less than or equal to the first threshold corresponding to the first model, this means that the ambient temperature is low and unsuitable for direct charging the target device 200, so the charging module controls the charging unit 3 to output a preheating current corresponding to the first model to perform pulse-heat on the battery of the target device 200, the temperature detected by the first unit 5 in real time is monitored in real time during heating the battery, and the charging working mode is set to be charging the target device 200 after the latest temperature detected at a collection time reaches the first threshold (which means that the preheating process is over). The controller 1 adjusts a MOSFET switching duty cycle by the PWM and controls a current intensity of the charging unit 3.

That is to say, the present disclosure is provided to avoid battery damage caused by a “one-size-fits all” charging strategy through the device identification and a temperature linkage thereof.

Optionally, the first threshold ranges from 0° C. to 8° C.

When the charging working mode is charging the target device 200, it is matched in the charging configuration corresponding to the first model according to the temperature detected by the first unit 5 in real time, to determine the charging control data, an instruction is sent to the charging unit 3 according to the charging control data, the charging unit 3 charges the target device 200 according to the instruction, in the whole charging process, the first unit 5 continuously detects temperature changes of the target device 200, and the charging module dynamically adjusts output parameters of the charging unit 3 from the charging configuration corresponding to the first model according to the real-time temperature of the target device 200, so that safety and high efficiency of the charging process are ensured, and an occurrence of overcharging or undercharging the battery is avoided until the target device 200 is fully charged.

The charge control data includes at least a charge power.

The charging configuration refers to a set of a series of rules and parameters when charging the target device 200. The charging configuration includes a plurality of sub-data that together determine charging-related parameters such as the charging power of the target device 200 under different conditions.

The charging configuration corresponding to the first model is a standard charging configuration of the device corresponding to the first model. The charging configuration corresponding to the first model can be data that is pre-stored in the system 100 in advance.

The embodiment of the present disclosure is provided to detect the temperature of the target device 200 and identify the device model of the target device 200, it can directly charge the battery when the temperature is greater than a corresponding threshold and pre-heats the battery and then recharges the battery when the temperature is less than the threshold value. In this way, the present disclosure can adapt to the charging environment, improve the charging efficiency, reduce the battery attenuation, protect safety of the battery and prolong a service life of the battery. Moreover, according to the charging configurations corresponding to different device models, the personalized requirements of different devices are automatically adapted, and a risk of overcharging or undercharging the battery is avoided.

In an embodiment of the present disclosure, the charging configuration corresponding to the first model includes a plurality of sub-data; and wherein
first sub-data includes: using a gradient strategy to determine a charging power when T1<T≤T2, wherein the gradient strategy includes at least three temperature subinterval strategies, and each temperature subinterval strategy corresponds to a preset linear increasing power curve; and wherein
second sub-data comprises: taking an optimal power corresponding to the device model of the target device 200 as the charging power when T2<T≤T3; and wherein
third sub-data includes: when T3<T≤T4, C=C₀-b×log_{α}(T−T3+1); and wherein
fourth sub-data includes: when T>T4, the charging power is 0; and wherein

T is the temperature detected by the first unit 5, C is the charging power, C₀ is the optimal power corresponding to the device model of the target device 200, b is an attenuation coefficient greater than 0, log is a logarithmic function, α is a constant greater than 1, and T1, T2, T3 and T4 are temperatures that are determined based on the device model of the target device 200.

T1, T2, T3, and T4 are temperatures that are preset according to the device model of the target device 200, and can be determined through limited experiments for different batteries.

Optionally, T1=0° C., T2=10° C., T3=35° C., T4=45° C., the first temperature subinterval strategy is a strategy corresponding to a temperature greater than 0° C. and less than or equal to 5° C., the second temperature subinterval strategy is a strategy corresponding to a temperature greater than 5° C. and less than or equal to 8° C., and the third temperature subinterval strategy is a strategy corresponding to a temperature greater than 8° C. and less than or equal to 10° C.

The temperature T1 in the charging configuration corresponding to the first model is equal to the first threshold corresponding to the first model.

A specific criteria for dividing the gradient strategy is a relationship between a temperature interval and a battery type.

The linear increasing power curve is a curve that increases in a linear relationship.

Alternatively, a horizontal ordinate of the linear increasing power curve is the temperature, a vertical ordinate is the power, and the power increases with the temperature. Thus, the temperature detected by the first unit 5 is used to find the corresponding power from the linear increasing power curve as the charging power.

Alternatively, the horizontal ordinate of the linear increasing power curve is the charging time, the vertical ordinate is the power, and the power increases with the charging time. Thus, the linear increasing power curve corresponding to the temperature detected by the first unit 5 is found, the power is found from the linear increasing power curve by adopting the charging time, and the found power is taken as the charging power.

An optimal power is corresponding to the device model of the target device 200, that is, a rated charging power is corresponding to the device model of the target device 200.

The attenuation coefficient is used for dynamically reducing the coefficient of the charging power when the temperature exceeds T3, and the larger the attenuation coefficient is, the faster the power attenuation is. It can be understood that log_{α}(T−T3+1) is calculated to be greater than 0 when T3<T≤T4. α is the base of the logarithmic function for adjusting the steepness of the power decay curve. α, b can be determined according to limited experiments, which are not limited herein.

The first sub-data is set, so that uneven heating of the internal resistance of the battery caused by performing direct high-power charging in a low-temperature environment can be avoided, charging safety is improved, and activity of the battery is gradually awakened and the charging efficiency is optimized by increasing the power in stages

The second sub-data is set to rapidly charge the battery of the target device 200 at a maximum power supported by the target device 200 within a suitable temperature range, thereby shortening the charging time thereof, avoiding overcharging risks through the specific configuration of the device, and prolonging the service life of the battery.

The third sub-data is set to gradually reduce the power in a high-temperature environment, so as to reduce heat generation of the battery of the target device 200, thereby preventing thermal runaway, and smoothly attenuating the logarithmic function to avoid impact of the battery caused by sudden power changes.

The fourth sub-data is set to thoroughly avoid expansion or explosion risks of the battery caused by performing high-temperature charging thereof.

The embodiment of the present disclosure is provided that the charging strategy is dynamically adjusted based on temperature intervals, the battery activity is wakened up by adopting the gradient increasing power in a low-temperature stage (T1<T≤T2) to avoid low-temperature damage thereof. The battery is quickly charged at the optimal power of the device in a suitable temperature interval (T2<T≤T3) to improve efficiency thereof; the power is smoothly attenuated through the logarithmic function in a high-temperature stage (T3<T≤T4), to balance the charging speed and the heat dissipation of the device; the charging process is stopped immediately when the temperature exceeds the safety threshold (T>T4), to thoroughly eliminate the overheat risk thereof, the safety adaptation and the efficient charging in a full-temperature range are realized, the service life of the battery is remarkably prolonged, and the user experience is improved.

Referring to FIG. 2, in an embodiment of the present disclosure, the system 100 further includes: an insulation isolation layer 8 arranged between the charging unit 3 and the speaker unit 4.

The insulation isolation layer 8 includes an aluminum silicate ceramic substrate, and a conductive coating set on an outer surface of a charging side 81 of the aluminum silicate ceramic substrate, wherein the outer surface of the charging side of the aluminum silicate ceramic substrate is a sawtooth waveform, an outer surface of a speaker side 82 of the aluminum silicate ceramic substrate is a trapezoidal waveform, and a ripple direction of the sawtooth waveform of the aluminum silicate ceramic substrate is orthogonal to a vibration direction of a diaphragm of the speaker unit 4.

The insulation isolation layer 8 is a composite structure composed of the aluminum silicate ceramic substrate (hereinafter referred to as a substrate) and the conductive coating, which is configured to physically isolate the charging unit 3 from the speaker unit 4.

Alternatively, a thickness of the aluminum silicate ceramic substrate is 2 mm (the thickness does not include a height of the trapezoidal waveform that is protruded and does not include a height of the sawtooth waveform that is protruded), and a thermal conductivity is 1.5 W/m·K.

Optionally, the conductive coating is made of graphene composite material. Optionally, a resistivity of the conductive coating is 10-3 Ω·cm, which is used to shield high-frequency electromagnetic interference thereof.

The aluminum silicate ceramic substrate is made of high-insulation and high-temperature-resistant materials. Referring to FIG. 4, the outer surface of the charging side 81 (the side close to the charging unit 3) of the substrate is the sawtooth waveform and the outer surface of the sound side 82 (the side close to the speaker unit 4) of the substrate is the trapezoidal waveform. The height and a space of the sawtooth waveforms can be determined based on limited experiments, which are not limited herein. Widths and depths of grooves of the trapezoidal waveform can be determined according to limited experiments, which are not limited herein.

The conductive coating is provided on the outer surface of the charging side 81 of the aluminum silicate ceramic substrate, so that high-frequency electromagnetic interference generated by the charging unit 3 can be shielded.

The sawtooth waveform is a continuous triangle protrusion that is formed on the outer surface of the charging side 81, which enhances a heat dissipation surface area and guides electromagnetic waves to be scattered.

Alternatively, the sawtooth waveform of the charging side 81 adopts a symmetrical sawtooth waveform, and the height and the space of each waveform are the same.

Alternatively, the sawtooth waveform of the charging side 81 adopts an asymmetric sawtooth waveform, that is, the spaces between the waveforms are different, a dense area enhances the heat dissipation area, while a sparse area reduces airflow resistance, so that the forced convection efficiency is improved.

The trapezoidal waveform is a trapezoidal groove that is formed on the outer surface of the speaker side 82, so that a reflection path of the sound wave is optimized, and standing wave interference is reduced.

Alternatively, the trapezoidal waveform of the speaker side 82 adopts the symmetrical trapezoidal waveform, and the width and the depth of the groove of each waveform are the same.

Alternatively, the trapezoidal waveform of the speaker side 82 adopts the asymmetric trapezoidal waveform, the widths of the grooves are gradually changed, wide grooves diffuse low-frequency sound waves, while narrow grooves directionally reflect high-frequency sound waves, so that the standing wave interference is reduced.

The orthogonal arrangement is that a ripple direction (the X-axis) of the sawtooth waveform is perpendicular to a vibration direction (the Y-axis) of the diaphragm of the speaker unit 4, so that the sound quality distortion caused by resonance is avoided.

It can be understood that the ripple direction of the sawtooth waveform is perpendicular to the vibration direction of the diaphragm, which may not be exactly perpendicular due to manufacturing errors thereof, and therefore an angle between the ripple direction of the sawtooth waveform and the vibration direction of the diaphragm can be 90°±5°.

The aluminum silicate ceramic substrate is prepared by using a hot-pressing sintering process, the sawtooth waveforms are processed on the charging side 81 through a laser engraving way, and the trapezoidal waveforms are processed on the speaker side 82 through the laser engraving way. The plasma spraying technology is used to form the coating on the surface of the charging side 81, and after the coating is formed, the coating is annealed, to enhance an adhesive force and conductivity thereof. The insulation isolation layer 8 is fixed between the charging unit 3 and the speaker unit 4, and a direction of the substrate is adjusted by using a laser positioning device, so that the ripple direction (the X-axis) of the sawtooth waveform is ensured to be approximately perpendicular to the vibration direction (the Y-axis) of the diaphragm.

The aluminum silicate ceramic substrate can be made by using a 3D printing (also known as an additive manufacturing or a laminated manufacturing) technology.

According to the embodiment, through the composite structure of the aluminum silicate ceramic substrate and the conductive coating, efficient physical isolation and electromagnetic shielding of the charging unit 3 and the speaker unit 4 are achieved, the heat dissipation efficiency is improved through designing the sawtooth waveform, the sound wave reflection path is optimized through the trapezoidal waveform, resonance interference is thoroughly eliminated through the orthogonal arrangement, the total harmonic distortion of the speaker unit 4 is reduced, meanwhile, the charging safety and high-fidelity sound quality output are ensured, and a cooperative optimization of the charging function and the speaker function is achieved.

In an embodiment of the present disclosure, the system 100 further includes a housing 9 and a speed-controllable fan, all of the speed-controllable fan, the controller 1, the power supply unit 2, the charging unit 3, the speaker unit 4 and the first unit 5 received in a receiving room 93 that is inside the housing 9, the controller 1 electrically connected to the speed-controllable fan, and the power supply unit 2 configured to supply power to the speed-controllable fan;
referring to FIG. 2, the housing including a fish-scale-shaped heat dissipation channel array and an air inlet 92, wherein the air inlet 92, the receiving room 93 and the fish-scale-shaped heat dissipation channel array cooperatively form an air passageway, the speed-controllable fan is configured to extract air from the receiving room 93 into the fish-scale-shaped heat dissipation channel array. The air is discharged to the outside of the housing 9 through the scale-shaped heat dissipation channel array.

The housing 9 can be a sealed structure made of high strength aluminum alloy, with the receiving room 93 being formed therein for integrating various units of the system 100.

Optionally, the surface of the housing 9 is anodized to enhance corrosion resistance thereof.

It can be understood that a shape of the housing 9 can be set as desired, which is not limited herein.

The speed-controllable fan adopts a brushless direct current fan, a rotating speed can be adjusted, and the power supply unit 2 supplies power to the speed-controllable fan by controlling the PWM signal. The controller 1 dynamically adjusts the rotational speed of the speed-controllable fan in accordance with the temperature (a sampling period of 1 second) detected by the first unit 5. Optionally, the controller 1 smoothes the rotation speed switching by the PID algorithm according to the temperature detected by the first unit 5, for avoiding sudden noise changes.

The PID algorithm is a control method which is the most mature and widely used in the control theory, and its core idea is to jointly regulate the output of the system 100 through three aspects of a current error (a proportional term), a historical error accumulation (an integral term) and an error change trend (a differential term), to achieve accurate control of a controlled object.

The fish-scale-shaped heat dissipation channel array, that is bionic heat dissipation channels 91 distributed on the surface of the housing 9, is arranged in a fish scale-shaped staggered manner for guiding airflow and increasing the heat dissipation area thereof. Optionally, the fish-scale-shaped heat dissipation channel array is made by using the 3D printing (also known as the additive manufacturing or the laminated manufacturing) technology.

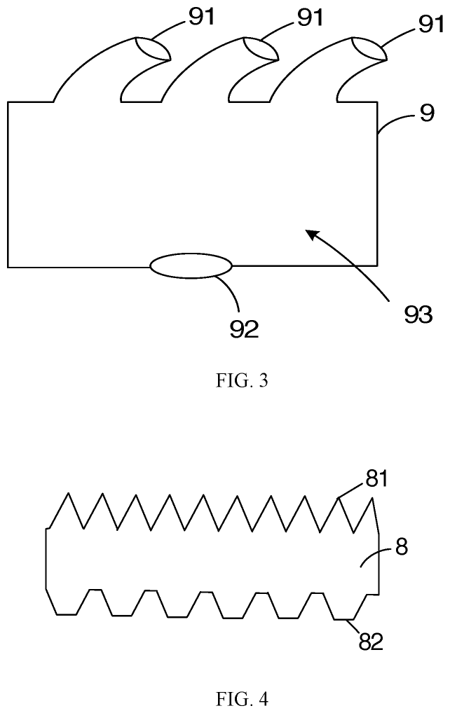

When the fish-scale-shaped heat dissipation channel array is overlooked, a single heat dissipation channel 91 in the fish-scale-shaped heat dissipation channel array is in a bionic-fish-scale shaped, a front end (a free end) is a semicircular arc shape, a rear end (that is connected with the housing 9) is in a tapered pointed tail shaped, a streamline form of natural fish scales is simulated, an edge of the front end is designed with a chamfer, to reduce turbulence noise when airflow passes therethrough, and meanwhile, the structural strength is improved. In the heat dissipation channel 91, a line connecting end points of the center axis of the heat dissipation channel 91 parallel to a direction of the airflow in the heat dissipation channel 91 forms an acute angle with the surface of the housing 9. Optionally, a preset angle is greater than 40° and less than 50°, which is 45°. FIG. 3 is a view from a side perspective showing the fish-scale-shaped heat dissipation channel array. As shown in FIG. 3, the heat dissipation channels 91 protrudes from the designated plane of the housing 9, thereby providing a specific dissipation path for the hot air in the receiving room 93 to be discharged from the receiving room 93, avoiding the hot air from staying in a region close to the housing 9, where it would cause heat energy to be conducted through the outside of the housing 9 into the receiving room 93, which is not conducive to heat dissipation thereof. The designated plane is a plane in which an area other than the fish-scale-shaped heat dissipation channel array is located on the side surface where the fish-scale-shaped heat dissipation channel array is located.

Optionally, a central axis of the heat dissipation channel is consistent with the airflow direction.

Optionally, the housing 9 includes a top portion, a plurality of side surfaces and a bottom portion, and the fish-scale-shaped heat dissipation channel array is arranged on the plurality of side surfaces of the housing 9.

The air inlets 92 are a honeycomb-shaped-hole array formed at the bottom portion of the housing 9 and are equipped with a dust-proof strainer mesh. Air enters the receiving room 93 through the air inlets 92 and the dust-proof strainer mesh.

Alternatively, in another embodiment of the present disclosure, a plurality of heat dissipation channels 91 (where the heat dissipation channels 91 are cylindrical) distributed in a honeycomb shape are used to be instead of the fish-scale-shaped heat dissipation channel array, that is, the air inlets 92, the receiving room 93 and the plurality of heat dissipation holes that is distributed in a honeycomb shape are cooperatively to form the air passageway.

The controller 1 dynamically adjusts the rotation speed of the speed-controllable fan based on the temperature detected by the first unit 5.

The embodiment of the present disclosure is provided that efficient active heat dissipation is achieved through the cooperative design of the fish-scale-shaped heat dissipation channel array and the speed-controllable fan.

In an embodiment of the present disclosure, a charging portion is arranged on an outer surface of the housing 9, and the charging unit 3 is configured to charge the target device 200 that is arranged on the charging portion; and wherein
the system 100 further includes a shielding cover covered on the charging portion and configured to shield an interference of the target device 200 on the speaker unit 4; and wherein
the system 100 further includes a phase-change heat dissipation unit 6 configured to reduce a temperature of the charging portion.

The charging portion can be a wireless charging area designed on the outer surface of the housing 9 or an area where the target device 200 is placed.

The shielding cover is a double-layer electromagnetic shielding structure made of Permalloy, and an inner layer of the structure is plated with copper and covers on the surface of the charging portion. When the target device 200 is placed on the charging portion, the shielding cover arranged on a side of the target device 200 that is away from the charging portion. The shielding cover made of Permalloy is fixed above the charging portion through a buckle, and the inner layer copper plating is grounded with the housing 9 through conductive adhesive, so that a Faraday cage structure is formed.

When the target device 200 is charged in the charging portion, adverse effects such as electromagnetic interference can be generated, and the shielding cover prevents the interference signals from propagating to the speaker unit 4 through its shielding characteristics (such as blocking and attenuating the electromagnetic field), so as to ensure the normal operation of the speaker unit 4, and avoid problems such as influence on sound quality or occurrence of noise.

The phase-change heat dissipation unit 6 is formed by embedding a phase-change material (for example, a paraffin-based phase-change material), encapsulating the phase-change material in an aluminum cavity, and in close contact with the charging portion, and conducting heat to the heat dissipation area (for example, an area where the fish scale-shaped heat dissipation channel array is located) of the housing 9 through a heat pipe. One end of the heat pipe is tightly attached to a backboard of the charging portion to take away heat energy of the backboard, and the other end of the heat pipe extends to the heat dissipation area. The heat pipe is directly in contact with the phase-change material, so that efficient heat transmission can be ensured. The heat pipe is used as a high-efficiency heat conduction component, and the heat generated by the charging portion is quickly conducted to the heat dissipation area through an evaporation-condensation cycle of the working medium (such as pure water).

Optionally, the phase-change heat dissipation unit 6 dissipates heat passively, without needing electrical connection thereof. The phase-change material of the phase-change heat dissipation unit 6 is usually performed passive heat dissipation, which does not need electrical connection thereof.

Optionally, the phase-change heat dissipation unit 6 is electrically connected with the controller 1 and the power supply unit 2, the controller 1 monitors the temperature of the charging portion in real time (the collecting end of the first unit 5 can be arranged on the charging portion, and is in contact with the target device 200), and when the temperature detected by the first unit 5 is greater than a preset temperature threshold, the phase-change material is started to absorb heat. The phase-change heat dissipation unit includes a phase-change material cavity, an electric heating element and the heat pipe, wherein the phase-change material cavity is provided with the phase-change material, the heat pipe is communicated with the phase-change material cavity, the electric heating element is electrically connected with the controller 1, the power supply unit 2 supplies power to the electric heating element, the controller 1 adjusts the power of the electric heating element according to the temperature detected by the first unit 5 so as to accelerate melting and heat absorption of the phase-change material in the phase-change material cavity to take away the heat energy of the backboard. When the temperature detected by the first unit 5 drops to the safe temperature range, the controller 1 turns off the electric heating element, and the phase-change material naturally solidifies to release heat. The phase transition process is actively adjusted through the electronic control way, so that the heat dissipation capacity can be quickly enhanced in a high-temperature environment, the target device is prevented from being overheated, the energy consumption is reduced at a low temperature, and the system endurance is prolonged.

The present disclosure thoroughly eliminates the interference to the speaker unit 4 during the charging process through the electromagnetic isolation between the charging portion and the shielding cover, which ensures high-fidelity sound quality, reduces the temperature of the charging portion to absorb the heat energy of the target device 200 by combining with the efficient heat conduction treatment of the heat pipe by the phase-change heat dissipation unit 6, further reduces the temperature of the target device 200, avoids the power frequency reduction or device damage caused by the overheating of the target device 200. The above three components (the charging portion, the shielding cover and the phase-change heat dissipation unit 6) are cooperatively to achieve comprehensive optimization of safe and fast charging, interference-free audio output and long-term heat dissipation, thereby significantly improving the reliability and user experiences of the system 100.

In an embodiment of the present disclosure, a first module and a playing module are respectively integrated with the controller 1; and wherein
the first module is configured to: obtain an evaluation signal, respond to the evaluation signal to obtain the charging working mode and a speaker working mode, obtain charging control data according to a first time interval if the charging working mode is charging the target device 200 and the speaker working mode is playing audios, and determine first compensation data based on the charging control data, and wherein the charging control data is determined based on the temperature detected by the first unit 5 and the charging configuration corresponding to the first model, the charging control data configured to control the charging unit 3 to charge the target device 200; and
the playing module configured to: obtain the first compensation data sent by the first module, compensate an audio segment to be played according to the first compensation data, and control the speaker unit 4 to play the audio segment to be played.

The first module is a real-time scheduling module integrated with the controller 1 and is responsible for coordinating the charging function and the sounding function, which includes mode detection, data acquisition and compensation calculation. The mode detection is configured to obtain the evaluation signal, and respond to the evaluation signal to obtain the charging working mode and the speaker working mode. The data acquisition is configured to obtain the charging control data according to the first time interval if the charging working mode is charging the target device 200 and the sound working mode is playing audios. The compensation calculation is configured to determine the first compensation data according to the charging control data.

The playing module is a real-time scheduling module integrated with the controller 1 and is responsible for controlling the speaker unit 4 to play audios.

In the present disclosure, it can be that the evaluation signal is actively triggered when either of the charging working mode and the speaker working mode is changed. It can also be that the evaluation signal is triggered by a user through a button on the housing 9. It can also be that the evaluation signal is sent by a third-party application. It can also be that the evaluation signal sent by a client that is compatible with the system 100. At the start time of each interval period of the default time interval, the evaluation signal is actively triggered. The interval period of the first time interval is smaller than the interval period of the default time interval.

If the charging working mode is charging the target device 200 and the speaker working mode is playing audios, this means that the system 100 is charged and plays audios at the same time, and the charging process will affect the process of playing audios, so that it is necessary to compensate for the audio, and obtain current charging control data at the start time of each interval period of the first time interval.

Optionally, the first compensation data is determined by a look-up table method according to the charging control data.

Parameters of the FIR filter are adjusted according to the first compensation data, and then the adjusted FIR filter is used to perform filtering treatment on the audio segment to be played, and send the audio segment to be played after being performed the filtering treatment to the speaker unit 4 for being played.

The primary function of the FIR filter (Finite Impulse Response, finite impulse response filter) is to filter and block frequency components of the audio. Specifically, the FIR filter can selectively retain or remove components of a specific frequency range as desired, thereby enabling processing and optimization of the audio.

The default time interval and the interval period of the first time interval can be set as required, which are not limited herein.

In the embodiment of the present disclosure, seamless coordination based on the charging control data and the sound functions is realized through the cooperative scheduling of the first module and the dynamic compensation of the playing module, so as to ensure that the speaker unit 4 can still output high-fidelity sound quality during the charging process, and avoid the interference or damage to the sound quality caused by the charging process, wherein the first compensation data is updated at the first time interval, so that the system 100 can be prevented from performing the audio compensation operation too frequently, unnecessary resource consumption is reduced, and the operation efficiency of the system 100 is improved.

In an embodiment of the present disclosure, the system 100 further includes: a second unit 7 configured to detect an electromagnetic signal of an environment where the speaker unit 4 is located, and a second module is integrated with the controller 1;
the second module configured to: obtain data obtained from the electromagnetic signal that is detected by the second unit 7, take the data as electromagnetic data, input the electromagnetic data into a first model that is pre-trained for performing classification prediction on the compensation data, to obtain second compensation data, perform compensation processing on standard control data corresponding to the first model according to the second compensation data, to obtain play control data; and
the playing module further configured to control the speaker unit 4 to play the audio segment to be played based on the play control data.

The second unit 7 is a high-sensitivity electromagnetic signal detection sensor, and attached to an outer shell of the speaker unit 4 to collect the electromagnetic interference signals in real time (such as Wi-Fi, Bluetooth and wireless charging high-frequency noise) in the environment where the speaker unit 4 is located.

The second module is an embedded AI (artificial intelligence) processing module, and integrates with the pre-trained first model, an input is the electromagnetic data, and an output is a compensation classification tag that is a scheme identification of the compensation scheme.

The electromagnetic data is frequency spectrum data of an electromagnetic signal time domain waveform (an optional sampling rate is 1 GS/s) after performing FFT transformation (Fourier transform), which includes information such as an amplitude, a frequency and harmonic components.

The first model that is the pre-trained is a multi-classification model that is the pre-trained. A model structure and a model training method of the first model can be selected from the related art, which will not be described in detail herein.

The electromagnetic data is input into the pre-trained first model to performing classification prediction of compensation data, a vector element with the maximum value is extracted from the predicted vector, and the compensation scheme corresponding to the compensation classification tag that is corresponding to the extracted vector element as second compensation data.

The second compensation data is a compensation parameter matrix. For example, when the interference corresponding to the electromagnetic data is a high-frequency interference, the compensation parameter matrix is used to trigger a band-stop filter, and select parameters of the band-stop filter. For another example, when the interference corresponding to the electromagnetic data is a low-frequency harmonic, a phase reversal cancellation algorithm is triggered and started through the compensation parameter matrix.

The standard control data corresponding to the first model is a default audio parameter corresponding to the first model. The default audio parameter includes, but is not limited to, an equalization curve and a sound effect configuration.

Performing compensation processing on the standard control data corresponding to the first model according to the second compensation data, that is to say, superposing the second compensation data and the standard control data.

Because the electromagnetic signals in the environment can lead to problems such as noise, and distortion in audio playing etc., according to the embodiment, through real-time electromagnetic environment sensing of the second unit 7, intelligent compensation of the second module and control of the playing module, the system 100 can effectively deal with the electromagnetic interference, and self-adaptive optimization of sound quality under complex electromagnetic interference scenarios can be achieved, wherein the accuracy of the determined second compensation data is improved through the first model, so that sound quality distortion caused by error compensation is avoided. The second compensation data is fused with the standard control data of the device model, so that the original sound effect style of the factory is reserved, the environmental interference is eliminated, and the effect of “original sound reproduction” is realized.

In an embodiment of the present disclosure, a third module is integrated with the controller 1 and configured to:
obtain the electromagnetic data within a preset time window as data to be analyzed according to a second time interval, determine third compensation data based on the data to be analyzed, and send the third compensation data to the playing module if the third compensation data is not empty; and wherein
the playing module configured to control the speaker unit to play the audio segment to be played based on the play control data, includes: compensating the audio segment to be played based on the third compensation data, and control the speaker unit 4 to play the audio segment to be played based on the play control data.

The third module is a real-time data analysis module, and integrates with a sliding window algorithm and a Fast Fourier Transform (FFT) accelerator, which is responsible for performing short-time depth analysis on the electromagnetic data to generate dynamic compensation parameters (that is, third compensation data).

According to the third compensation data, the audio segment to be played is compensated, wherein an original audio segment to be played can be compensated, or the audio segment to be played after the first compensation data is compensated can be compensated again.

At the start time of each interval period of the second time interval, taking the start time as an ending time of a preset time window, obtaining all the electromagnetic data within the preset time window, and taking all the electromagnetic data that is obtained as data to be analyzed.

The interval period of the second time interval can be set as needed, which is not limited herein.

The third compensation data is a dynamic correction parameter generated based on transient interference characteristics. Optionally, the third compensation data adopts dynamic gain compression.

If the third compensation data is not empty, the third compensation data is sent to the playing module when a situation of needing the compensation is detected, and if the third compensation data is empty, it means that the situation of needing the compensation is not detected, and the third compensation data is not needed to be sent to the playing module.

The sliding window algorithm is used to detect an energy sudden increase region of the data to be analyzed, which is marked as the transient interference characteristics, the transient interference characteristics that are extracted are input into a pre-trained second model for performing classification prediction, a vector element with the maximum value is extracted from the predicted vector, and taking the classification category corresponding to the vector element as third compensation data.

The second model that is pre-trained is a multi-classification model that is pre-trained. A model structure and a model training method of the second model can be selected from the related art, which will not be described in detail herein.

The playing module adopts the third compensation data to update a dynamic gain compressor, and adopts the dynamic gain compressor to process the audio segment to be played, to obtain the audio segment to be played after the third compensation data is compensated.

The dynamic gain compressor is an audio processing device or an algorithm, which is configured to receive the audio signal, detects a level of the audio signal, and reduce the gain according to the compression ratio when exceeding the threshold, an attack time and a release time are used to control a speed of adjusting the gain.

Because the electromagnetic signals in the environment are dynamically changed, the embodiment of the present disclosure is provided to realize dynamic compensation by obtaining the data at the second time interval and determining the compensation data, to realize real-time optimization of sound quality in complex electromagnetic environments. The audio segment is played after being compensated, so that playing deviations caused by changes of the electromagnetic environment can be effectively corrected, for example, problems of audio distortion, noise and other issues caused by the electromagnetic interference are eliminated, the quality of the audio that is played by the speaker unit 4 is further improved, and a user can still enjoy high-quality audio experience under complex and dynamically changing electromagnetic environments.

In an embodiment of the present disclosure, a fourth module is integrated with the controller 1 and configured to:
obtain a mandatory signal, respond to the mandatory signal, obtain a real-time charging power of the charging unit 3 according to a third time interval, and generate a prohibition signal if the real-time charging power is greater than a preset power corresponding to the first model; otherwise, generate an unlocking signal if the real-time charging power is not greater than a preset power corresponding to the first model; and wherein
the playing module is further configured to: respond to the prohibition signal to control the speaker unit 4 to enter a silent state, and respond to the unlocking signal to control the speaker unit 4 to enter an active state.

The mandatory signal is an external trigger signal (such as long pressing a “safe-mode” button for 3 seconds) or a self-check abnormal signal of the system 100 (such as the temperature exceeds a second threshold).

The real-time charging power of the charging unit 3 is an instantaneous power that is output by the charging unit 3.

The preset power is a safety power threshold corresponding to the device model and is stored in a non-volatile memory of the controller 1.

In the silent state, the speaker unit 4 does not play any audio. In the active state, the speaker unit 4 plays the audio according to the instruction of the controller 1 or waits for the instruction of the controller 1.

The interval period of the third time interval can be set as needed, which is not limited herein.

In the embodiment of the present disclosure, when the mandatory signal is input to the fourth module, the fourth module obtains the real-time charging power of the charging unit 3 according to the third time interval. If the obtained real-time charging power is larger than the preset power, it is indicates that the charging power is too great, which may pose potential safety hazards or affect normal operation of other components; at this time, the fourth module generates the prohibition signal. After receiving the prohibition signal, the playing module controls the speaker unit 4 to enter the silent state, that is, to stop playing the speaker unit 4. The technical effect has the advantages that instability factors possibly brought by operating the speaker unit 4 under a high charging power can be avoided, and meanwhile, the overall risk of device failure caused by the excessive charging power can be prevented. On the contrary, if the real-time charging power is not greater than the preset power, the fourth module generates the unlocking signal, and the playing module controls the speaker unit 4 to enter the active state after the playing module receives the unlocking signal, so that the speaker unit 4 can play audios normally. The above mechanism can ensure that the sound function is not affected under the condition of a normal charging power, so that the safety of the device is ensured, the user can normally use the sound function, and the overall stability and usage experience of the device are improved.

In an embodiment of the present disclosure, the charging module is further configured to:
respond to the start signal, obtain a power soft switching configuration corresponding to the first model as a target configuration; and
control the charging unit 3 to charge the target device 200 based on the target configuration, the temperature detected by the first unit 5, and the charging configuration corresponding to the first model.

The power soft switching configuration is a smooth transition strategy that dynamically adjusts the charging power based on the device model, characteristics of the battery, and an ambient temperature, a core objective is to balance the charging speed and the battery health, to prevent damage or performance degradation caused by power fluctuations. The power soft switching configuration is configured to limit a change rate of the power to prevent a step current thereof. The target configuration is configured to restrict the maximum difference of changes of the charging power within a preset duration. Limiting the power difference can maintain stable circuit parameters, ensure controllable change rates of temperatures, avoid rapid temperature increases, and enhance charging safety thereof.

When the charging working mode is charging the target device 200, the temperature detected by the first unit 5 is matched in the charging configuration corresponding to the first model, to determine the charging control data, and send instructions to the charging unit 3 based on the target configuration and the charging control data. That is to say, the embodiment of the present disclosure does not directly send instructions to the charging unit 3 based on the charging control data, but determines the data for controlling the charging unit 3 based on the charging control data under a constraint of the target configuration, generates the instructions based on the data, and then sends the instructions to the charging unit 3.

The embodiment of the present disclosure is provided to obtain dual optimization of efficiency and safety during the charging process through a dynamic control strategy that the power soft switching configuration is combined with a temperature linkage. The power soft switching configuration can avoid battery polarization effect caused by current step changes (battery polarization effects not only reduce energy efficiency, limit the charging speed, but also intensify heat generation and material aging, ultimately threatening safety and shortening a service life of the battery), which improves charging efficiency, and extends a service life of the battery.

One of ordinary skill in the related art can clearly understand that, for the convenience and simplicity of description, only the above functional units and modules are given as an example to describe the specification. In practical applications, the above functions can be assigned to different functional units or modules according to actual requirements, that is, the internal structure of the device can be divided into different functional units or modules to complete all or part of the functions described above.

Although the features and elements of the present disclosure are described as embodiments in particular combinations, each feature or element can be used alone or in other various combinations within the principles of the present disclosure to the full extent indicated by the broad general meaning of the terms in which the appended claims are expressed. Any variation or replacement made by one of ordinary skill in the related art without departing from the spirit of the present disclosure shall fall within the protection scope of the present disclosure.

What is claimed is:

1. An intelligent charging sound system based on device identification comprising: a controller, a power supply unit, a charging unit, a speaker unit and a first unit, the power supply unit configured to supply power to the controller, the charging unit, the speaker unit and the first unit, and the first unit configured to detect a temperature of a target device; and wherein a charging module is integrated with the controller and configured to:
obtain a start signal, respond to the start signal, and obtain a device model of the target device as a first model;
obtain the temperature detected by the first unit, and take the temperature as a first temperature;
setting a charging working mode to be charging the battery if the first temperature is greater than a first threshold corresponding to the first model, otherwise, controlling the charging unit to apply a current to the target device for preheating a battery of the target device based on the first model and the temperature detected by the first unit, and setting the charging working mode to be charging the battery after preheating the battery; and wherein
when the charging working mode is charging, the charging unit is controlled to charge the target device based on the temperature detected by the first unit and a charging configuration corresponding to the first model; and wherein
the system further comprises a housing and a speed-controllable fan, and all of the speed-controllable fan, the controller, the power supply unit, the charging unit, the speaker unit and the first unit received in a receiving room that is inside the housing, the controller electrically connected to the speed-controllable fan, and the power supply unit configured to supply power to the speed-controllable fan;
the housing comprising a fish-scale-shaped heat dissipation channel array and an air inlet, wherein the air inlet, the receiving room and the fish-scale-shaped heat dissipation channel array cooperatively form an air passageway, and the speed-controllable fan is configured to extract air from the receiving room into the fish-scale-shaped heat dissipation channel array;
a charging portion arranged on an outer surface of the housing, and the charging unit configured to charge the target device that is arranged on the charging portion; and wherein
the system further comprises a shielding cover covered on the charging portion and configured to shield an interference that the target device applies for the speaker unit; and wherein
the system further comprises a phase-change heat dissipation unit electrically connected to both the controller and the power supply unit, and configured to reduce a temperature of the charging portion; and wherein
a first module and a playing module are respectively integrated with the controller;
the first module configured to: obtain an evaluation signal, respond to the evaluation signal to obtain the charging working mode and a speaker working mode, obtain charging control data according to a first time interval if the charging working mode is charging the target device and the speaker working mode is playing audios, and determine first compensation data based on the charging control data, and wherein the charging control data is determined based on the temperature detected by the first unit and the charging configuration corresponding to the first model, the charging control data configured to control the charging unit to charge the target device;
the playing module configured to: obtain the first compensation data sent by the first module, compensate an audio segment to be played according to the first compensation data, and control the speaker unit to play the audio segment to be played; and wherein
the system further comprises: a second unit configured to detect an electromagnetic signal of an environment where the speaker unit is located, and a second module integrated with the controller;
the second module configured to: obtain data obtained from the electromagnetic signal that is detected by the second unit, take the data as electromagnetic data, input the electromagnetic data into a first model that is pre-trained for performing classification prediction on the compensation data, to obtain second compensation data, perform compensation processing on standard control data corresponding to the first model according to the second compensation data, to obtain play control data;
the playing module further configured to control the speaker unit to play the audio segment to be played based on the play control data; and wherein a third module is integrated with the controller and configured to:
obtain the electromagnetic data within a preset time window as data to be analyzed according to a second time interval, determine third compensation data based on the data to be analyzed, and send the third compensation data to the playing module if the third compensation data is not empty; and wherein
the playing module configured to control the speaker unit to play the audio segment to be played based on the play control data, comprises: compensating the audio segment to be played based on the third compensation data, and controlling the speaker unit to play the audio segment to be played based on the play control data.

2. The system as claimed in claim 1, wherein the charging configuration corresponding to the first model comprises a plurality of sub-data; and wherein first sub-data comprises: using a gradient strategy to determine a charging power when T1<T≤T2, wherein the gradient strategy comprises at least three temperature subinterval strategies, and each temperature subinterval strategy corresponds to a preset linear increasing power curve; and wherein
second sub-data comprises: taking an optimal power corresponding to the device model of the target device as the charging power when T2<T≤T3; and wherein
third sub-data comprises: when T3<T≤T4, C=C₀-b×log_{α}(T−T3+1); and wherein
fourth sub-data comprises: when T>T4, the charging power is 0; and wherein T is the temperature detected by the first unit, C is the charging power, C₀ is the optimal power corresponding to the device model of the target device, b is an attenuation coefficient greater than 0, log is a logarithmic function, α is a constant greater than 1, and T1, T2, T3 and T4 are temperatures that are determined based on the device model of the target device.

3. The system as claimed in claim 1, wherein the system further comprises an insulation isolation layer arranged between the charging unit and the speaker unit and comprising:
an aluminum silicate ceramic substrate, and a conductive coating set on an outer surface of a charging side of the aluminum silicate ceramic substrate, wherein the outer surface of the charging side of the aluminum silicate ceramic substrate is a sawtooth waveform, an outer surface of a speaker side of the aluminum silicate ceramic substrate is a trapezoidal waveform, and a ripple direction of the sawtooth waveform of the aluminum silicate ceramic substrate is orthogonal to a vibration direction of a diaphragm of the speaker unit.

4. The system as claimed in claim 1, wherein a fourth module is integrated with the controller and configured to:
obtain a mandatory signal, respond to the mandatory signal, obtain a real-time charging power of the charging unit according to a third time interval, and generate a prohibition signal if the real-time charging power is greater than a preset power corresponding to the first model; otherwise, generate an unlocking signal if the real-time charging power is not greater than a preset power corresponding to the first model; and wherein
the playing module is further configured to: respond to the prohibition signal to control the speaker unit to enter a silent state, and respond to the unlocking signal to control the speaker unit to enter an active state.

5. The system as claimed in claim 1, wherein the charging module is further configured to:
respond to the start signal, obtain a power soft switching configuration corresponding to the first model as a target configuration; and
control the charging unit to charge the target device based on the target configuration, the temperature detected by the first unit, and the charging configuration corresponding to the first model.
